(19) United States
(12) Patent Application Publication
(10) Pub. No.: US 2013/0336805 A1
(43) Pub. Date: Dec. 19, 2013

(54) FAN CONTROL DEVICE AND FAN CONTROL METHOD

(71) Applicant: FUJITSU LIMITED, Kawasaki-shi (JP)

(72) Inventors: Kazuharu SHIBATA, Shinagawa (JP); Satoshi MATSUNAGA, Kawasaki (JP); Tsuyoshi KURIBAYASHI, Inagi (JP)

(73) Assignee: FUJITSU LIMITED, Kawasaki-shi (JP)

(21) Appl. No.: 13/968,172

(22) Filed: Aug. 15, 2013

Related U.S. Application Data
(63) Continuation of application No. PCT/JP2011/053561, filed on Feb. 18, 2011.

(51) Int. Cl. H05K 7/20; F04D 15/00

(52) U.S. Cl. CPC H05K 7/20209; F04D 15/0066
USPC 417/44.1

(57) ABSTRACT

A fan control device includes a PWM generating circuit, a PWM switching circuit, and a switching instructing unit. The PWM generating circuit generates an arbitrary signal controlling rotation of a fan for cooling an MXM card. The PWM switching circuit is located between the MXM card and the fan, and switches output to the fan from the arbitrary signal generated by the PWM generating circuit to a signal output from the MXM card. The switching instructing unit issues a switching instruction to the PWM switching circuit at predetermined timing. Consequently, the fan control device can appropriately control the fan for cooling a heat-generating component.

### CROSS-REFERENCE TO RELATED APPLICATION

This application is a continuation of International Application No. PCT/JP2011/053561, filed on Feb. 18, 2011, the entire contents of which are incorporated herein by reference.

### FIELD

The embodiments discussed herein are directed to a fan control device and the like.

### BACKGROUND

When a heat-generating component with a high amount of heat generation, such as an MXM (Mobile PCI-Express Module) card, is mounted in an electronic device, a fan is installed in the electronic device to cool the heat-generating component. FIG. 14 is an explanatory diagram of a case where an MXM card is cooled by one large fan. As illustrated in FIG. 14, an MXM card 200 is connected to a large fan 201. A driver of the MXM card 200 running on an operating system (OS) controls the fan 201 by a PWM (Pulse Width Modulation) signal according to temperature detected by a thermal integrated circuit (IC) 200t.

To increase the cooling effect of a fan, an MXM card may be cooled by two small fans. FIG. 15 is an explanatory diagram of a case where an MXM card is cooled by two small fans. As illustrated in FIG. 15, an MXM card 300 is connected to two small fans 301 and 302. A driver of the MXM card 300 running on an OS controls the fans 301 and 302 by a PWM signal according to temperature detected by a thermal IC 300t.

Furthermore, a control device for controlling a fan has been developed. If a voltage value corresponding to the duty cycle of a PWM signal is higher than a reference voltage value when a system has booted, the control device controls the fan to rotate at variable revolving speed on the basis of the PWM signal. On the other hand, if a voltage value corresponding to the duty cycle of a PWM signal is lower than the reference voltage value, the control device maintains the fan revolving speed at fixed low speed, thereby reducing noise produced by the fan.
Patent document 1: Japanese Laid-open Patent Publication No. 2007-43890
Patent document 2: Japanese Laid-open Patent Publication No. 2001-298989

However, conventional control of a fan for cooling a heat-generating component may not appropriately control the fan. For example, a driver of an MXM card controls a fan by a PWM signal according to temperature of the MXM card; however, until an OS has booted, the driver does not control the fan. Therefore, until the OS has booted, the fan is controlled by a PWM signal controlling the fan revolving speed to the maximum or a PWM signal controlling the fan revolving speed to zero. When the fan is controlled by a PWM signal controlling the revolving speed to the maximum, there is a problem that a user mat feel the sound of the fan is noisy until the OS has booted. Furthermore, when the fan is controlled by a PWM signal controlling the revolving speed to zero, there is a problem that an amount of heat generated by the heat-generating component is increased with the boot-up of the OS.

Incidentally, in control of a fan for cooling a heat-generating component, the above-described problems arise not only until the boot-up of a system but also during normal operation after the system has booted. For example, even when a driver controls a fan by a PWM signal according to temperature, some users may feel that the sound of the fan is noisy.

### SUMMARY

According to an aspect of an embodiment, a fan control device includes a signal generating circuit, a switching circuit and a switching instructing unit. The signal generating circuit generates an arbitrary signal controlling rotation of a fan for cooling a heat-generating component. The switching circuit is located between the heat-generating component and the fan, and switches output to the fan from the arbitrary signal generated by the signal generating circuit to a signal output by the heat-generating component. The switching instructing unit issues a switching instruction to the switching circuit at predetermined timing.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a functional block diagram illustrating a configuration of a fan control device according to a first embodiment;

FIG. 2 is a flowchart illustrating a procedure of fan control according to the first embodiment;

FIG. 3 is a block diagram illustrating a configuration of a fan control device according to a variation of the first embodiment;

FIG. 4 is a flowchart illustrating a procedure of fan control according to the variation of the first embodiment;

FIG. 5 is a diagram illustrating a time chart of the fan control according to the first embodiment;

FIG. 6 is a block diagram illustrating a configuration of a fan control device according to a second embodiment;

FIG. 7 is a flowchart illustrating a procedure of fan control according to the second embodiment;

FIG. 8 is a diagram for explaining an example of a default screen of a fan control application;

FIG. 9 is a diagram for explaining a setting example of the screen of the fan control application when a user wants to reduce the sound produced by the rotation of fans;

FIG. 10 is a diagram for explaining a setting example of the screen of the fan control application when the user wants to lower the temperature of a device body;

FIG. 11 is a diagram illustrating an example of the concept of a mobile workstation using the fan control according to the embodiment;

FIG. 12 is a diagram illustrating an example of the mounting location of a VGA card in a body part;

FIG. 13 is a diagram illustrating an example of a hardware configuration of the mobile workstation using the fan control according to the embodiment;

FIG. 14 is an explanatory diagram of a case where an MXM card is cooled by one large fan; and

FIG. 15 is an explanatory diagram of a case where an MXM card is cooled by two small fans.

### DESCRIPTION OF EMBODIMENTS

Preferred embodiments of the present invention will be explained with reference to accompanying drawings. Incidentally, in the embodiments described below, an MXM (Mobile PCI-Express Module) card, such as a VGA (Video Graphics Array) card, is described as an object component. However, the present invention is not limited to the embodiments, and an object component can be any component as long as the component generates heat while a system is running and is cooled by a fan.

### [a] First Embodiment

Configuration of Fan Control Device According to First Embodiment

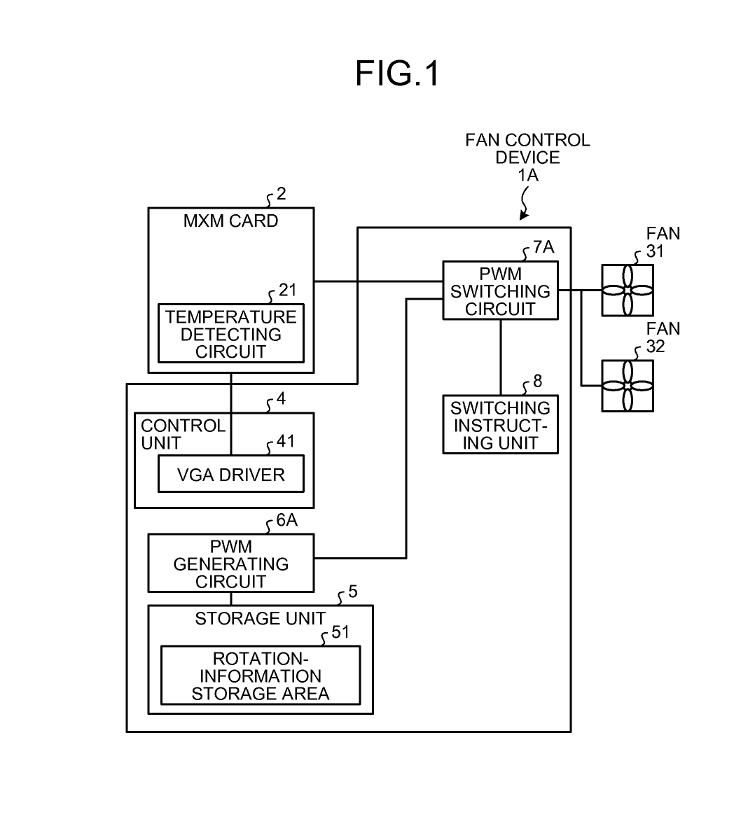

FIG. 1 is a functional block diagram illustrating a configuration of a fan control device according to a first embodiment. As illustrated in FIG. 1, a fan control device 1A includes a control unit 4, a storage unit 5, a PWM (Pulse Width Modulation) generating circuit 6A, a PWM switching circuit 7A, and a switching instructing unit 8.

The fan control device 1A is connected to an MXM card 2 and fans 31 and 32. Until control has been switched from a basic input/output system (BIOS) to an operating system (OS), the fan control device 1A controls the rotation of the fans 31 and 32 for cooling the MXM card 2 by an arbitrary PWM signal. Then, at timing when the control has been switched from the BIOS to the OS, the fan control device 1A switches output to the fans 31 and 32 from the arbitrary PWM signal to a temperature-based PWM signal output from the MXM card 2.

The MXM card 2 is a graphics card compliant with the PCI-Express-based notebook computer graphics expansion interface standard (MXM). The MXM card 2 includes a temperature detecting circuit 21 that detects temperature. Namely, the MXM card 2 is a heat-generating component that is mounted on a main board of a body part of a device, such as a notebook computer, and generates heat while the device is in operation. Incidentally, the MXM card 2 is, for example, a VGA card; besides this, the MXM card 2 can be a graphics processing unit (GPU) and any other components as long as the components are a heat-generating component that generates heat while the device is in operation.

The fans 31 and 32 are fans for cooling the MXM card 2. The fans 31 and 32 each include a motor and blades attached to a rotating shaft of the motor. The fans 31 and 32 rotate on the basis of, for example, a PWM signal from the PWM switching circuit 7A to be described later. This PWM signal has a waveform corresponding to fan revolving speed, and a duty cycle and a duty ratio vary according to the fan revolving speed. Incidentally, the fan revolving speed here means, for example, the number of revolutions per second.

The control unit 4 includes a VGA driver 41 which runs on the OS. The VGA driver 41 controls the rotation of the fans 31 and 32 according to temperature of the MXM card 2. For example, the VGA driver 41 causes the MXM card 2 to output a PWM signal according to temperature detected by the temperature detecting circuit 21 to the PWM switching circuit 7A. The VGA driver 41 is not activated until control has been switched from the BIOS to the OS, and therefore the VGA driver 41 does not control a PWM signal according to temperature of the MXM card 2. Accordingly, until the control has been switched from the BIOS to the OS, the MXM card 2 outputs a PWM signal controlling the fan revolving speed to high level including the maximum number of revolutions or a PWM signal controlling the fan revolving speed to low level including non-rotation. Then, after the control has been switched from the BIOS to the OS, the VGA driver 41 causes the MXM card 2 to output a PWM signal according to temperature of the MXM card 2. Incidentally, the control unit 4 is, for example, an integrated circuit, such as an application specific integrated circuit (ASIC) and a field programmable gate array (FPGA), or an electronic circuit, such as a central processing unit (CPU), a micro processing unit (MPU), and a GPU. Furthermore, the control unit 4 can be realized by a program, such as the VGA driver 41, causing, for example, a GPU to function.

The storage unit 5 includes a rotation-information storage area 51. Incidentally, the storage unit 5 includes, for example, semiconductor memory devices, such as a random access memory (RAM) and a flash memory, and storage devices, such as a hard disk and an optical disk. Arbitrary revolving speed of the fans 31 and 32 is stored in the rotation-information storage area 51. The arbitrary revolving speed here means revolving speed which is enough not to make a user of the device feel that the sound of the fans 31 and 32 is noisy and is enough to cool the MXM card 2. For example, the arbitrary revolving speed is 66% of the maximum number of revolutions per second.

The PWM generating circuit 6A generates an arbitrary PWM signal controlling the rotation of the fans 31 and 32 for cooling the MXM card 2. For example, the PWM generating circuit 6A reads out the arbitrary revolving speed stored in the rotation-information storage area 51, and generates a PWM signal corresponding to the read arbitrary revolving speed. Then, the PWM generating circuit 6A outputs the generated PWM signal to the PWM switching circuit 7A.

The PWM switching circuit 7A is located between the MXM card 2 and the fans 31 and 32, and switches output to the fans 31 and 32 from an arbitrary PWM signal generated by the PWM generating circuit 6A to a PWM signal output from the MXM card 2 at predetermined timing. For example, the PWM switching circuit 7A receives an arbitrary PWM signal generated by the PWM generating circuit 6A, and further receives a PWM signal output from the MXM card 2. Until instructed by the switching instructing unit 8 to be described later, the PWM switching circuit 7A outputs the arbitrary PWM signal out of the received PWM signals to the fans 31 and 32. Then, at timing instructed by the switching instructing unit 8, the PWM switching circuit 7A switches output to the fans 31 and 32 from the arbitrary PWM signal to the PWM signal output from the MXM card 2.

The switching instructing unit 8 issues a switching instruction to the PWM switching circuit 7A at predetermined timing. For example, as the predetermined timing, when the control has been switched from the BIOS to the OS, the switching instructing unit 8 issues a switching instruction to the PWM switching circuit 7A. Namely, when the control has been switched from the BIOS to the OS, the VGA driver 41 can be activated; therefore, after the activation, the VGA driver 41 can control a PWM signal according to temperature. Accordingly, at the timing when the control has been switched from the BIOS to the OS, the switching instructing unit 8 instructs the PWM switching circuit 7A to switch from the arbitrary PWM signal to the PWM signal output from the MXM card 2. Upon receipt of this instruction, the PWM switching circuit 7A switches the output from the arbitrary PWM signal to a PWM signal according to temperature.

Procedure of Fan Control According to First Embodiment

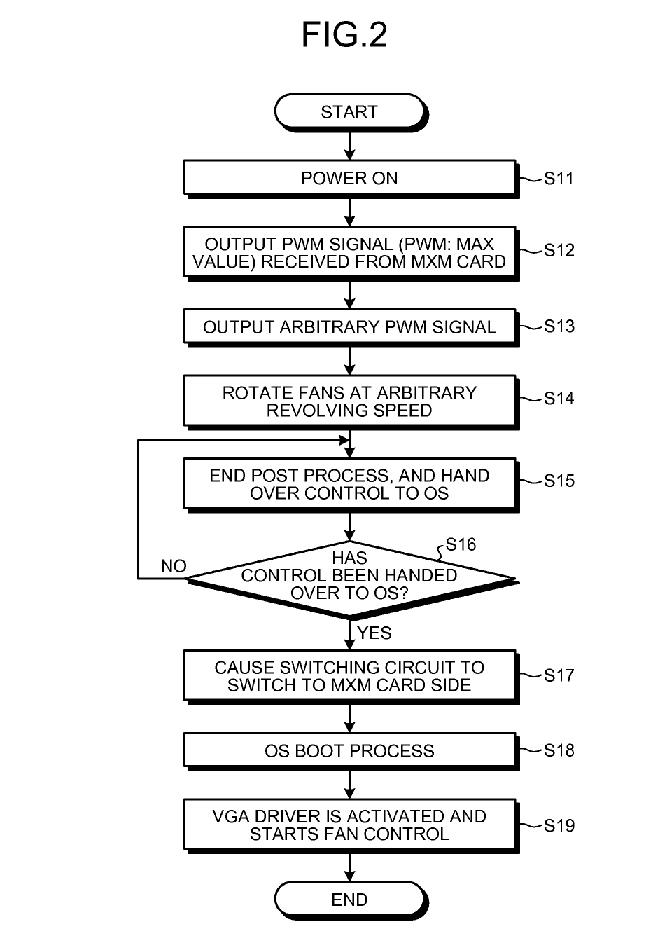

Subsequently, a procedure of fan control according to the first embodiment is explained with reference to FIG. 2. FIG. 2 is a flowchart illustrating the procedure of the fan control according to the first embodiment. In an example illustrated in FIG. 2, a default value of a PWM signal to be output from the MXM card 2 has been set to high (“H”) level.

First, when the power to a device equipped with the MXM card 2, the fans 31 and 32, and the fan control device 1A is turned on (Step S11), the BIOS initiates a power-on self test (POST) process. Then, the MXM card 2 sets a PWM signal to high level, which is the default level, and outputs the PWM signal to the PWM switching circuit 7A (Step S12). For example, the MXM card 2 outputs a PWM signal controlling the revolving speed of the fans 31 and 32 to the maximum to the PWM switching circuit 7A. As an example, the MXM card 2 outputs a PWM signal resulting in a duty ratio of 1.0.

In parallel with the PWM signal output from the MXM card 2, the PWM generating circuit 6A generates an arbitrary PWM signal, and outputs the arbitrary PWM signal to the PWM switching circuit 7A (Step S13). The arbitrary PWM signal means a PWM signal corresponding to revolving speed which is enough not to make a user of the device feel that the sound of the fans 31 and 32 is noisy and is enough to cool the MXM card 2.

Then, the fans 31 and 32 receive the arbitrary PWM signal from the PWM switching circuit 7A, and rotate at revolving speed corresponding to the received arbitrary PWM signal (Step S14). As a result, the sound produced by the fans 31 and 32 is reduced as compared with that produced by the rotation at the revolving speed corresponding to the high-level PWM signal.

After that, the BIOS ends the POST process, and hands over the control to the OS (Step S15). Then, the switching instructing unit 8 determines whether the BIOS has handed over the control to the OS, i.e., the control has been switched from the BIOS to the OS (Step S16). When having determined that the BIOS has not yet handed over the control to the OS (NO at Step S16), the switching instructing unit 8 repeats the determination until it is determined that the BIOS has handed over the control to the OS.

On the other hand, when having determined that the BIOS has handed over the control to the OS (YES at Step S16), the switching instructing unit 8 issues a switching instruction to the PWM switching circuit 7A (Step S17). Upon receipt of this instruction, the PWM switching circuit 7A switches output to the fans 31 and 32 from the arbitrary PWM signal to the PWM signal output from the MXM card 2.

Then, the OS performs a boot process (Step S18). When the OS has booted, the VGA driver 41 is activated and starts controlling the fans for cooling the MXM card 2 (Step S19). After that, the VGA driver 41 causes the MXM card 2 to output a PWM signal according to temperature of the MXM card 2.

In FIG. 2, a default value of a PWM signal to be output from the MXM card 2 has been set to high (“H”) level. However, a default value of a PWM signal to be output from the MXM card 2 can be set to low (“L”) level. When a default value has been set to low level, at Step S12, the MXM card 2 sets a PWM signal to low level, which is the default level, and outputs the PWM signal to the PWM switching circuit 7A. For example, the MXM card 2 outputs a PWM signal controlling the rotation of the fans 31 and 32 to non-rotation to the PWM switching circuit 7A. As an example, the MXM card 2 outputs a PWM signal resulting in the minimum duty ratio of 0.0. Then, the fans 31 and 32 receive the arbitrary PWM signal from the PWM switching circuit 7A, and rotate at revolving speed corresponding to the received arbitrary PWM signal. As a result, the fans 31 and 32 can cool down heat generated by a heat-generating component (the MXM card 2) rotating as compared with non-rotation corresponding to the low-level PWM signal.

Incidentally, the fan control device 1A according to the first embodiment uses a PWM signal as a signal controlling the rotation of the fans 31 and 32. However, a signal controlling the rotation of the fans 31 and 32 is not limited to this, and the fan control device 1A according to the first embodiment can use a voltage-level signal as a signal controlling the rotation of the fans 31 and 32.

Variation of Fan Control Device According to First Embodiment

As a variation of the fan control device according to the first embodiment, a case where a signal controlling the rotation of the fans 31 and 32 is a voltage-level signal is explained.

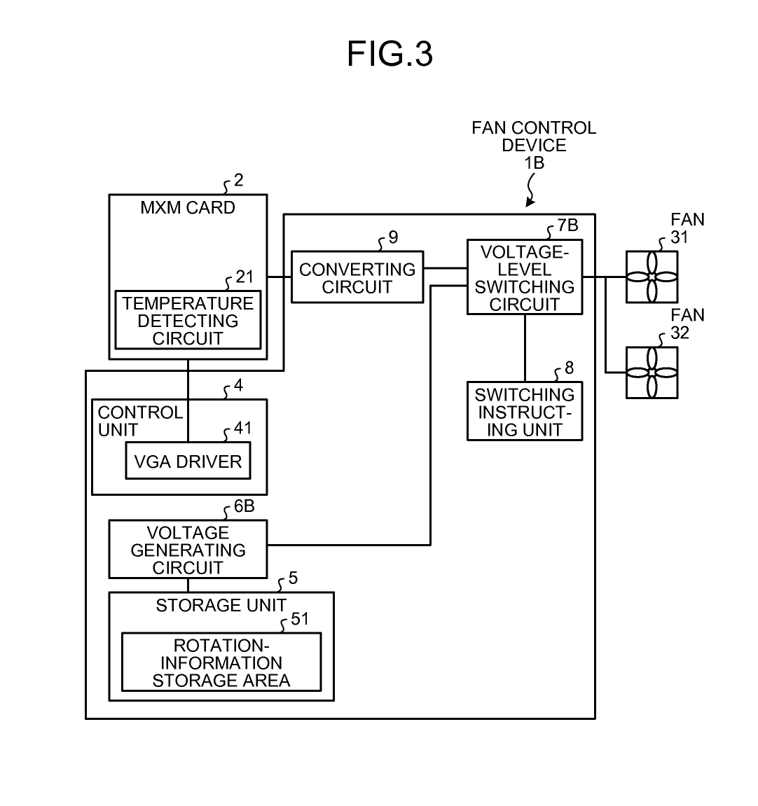

FIG. 3 is a block diagram illustrating a configuration of a fan control device according to the variation of the first embodiment. Incidentally, the same component as in the fan control device 1A illustrated in FIG. 1 is denoted by the same reference numeral, and description of the component and its operation is omitted. A fan control device 1B according to the variation differs from the fan control device 1A according to the first embodiment in that the fan control device 1B includes a voltage generating circuit 6B and a voltage-level switching circuit 7B instead of the PWM generating circuit 6A and the PWM switching circuit 7A. Furthermore, the fan control device 1B according to the variation differs from the fan control device 1A according to the first embodiment in that the fan control device 1B further includes a converting circuit 9.

The voltage generating circuit 6B generates an arbitrary voltage-level signal controlling the rotation of the fans 31 and 32 for cooling the MXM card 2. For example, the voltage generating circuit 6B reads out arbitrary revolving speed stored in the rotation-information storage area 51, and generates a voltage-level signal corresponding to the read arbitrary revolving speed. Then, the voltage generating circuit 6B outputs the generated voltage-level signal to the voltage-level switching circuit 7B to be described later.

The converting circuit 9 is located between the MXM card 2 and the voltage-level switching circuit 7B to be described later, and converts a PWM signal output from the MXM card 2 into a voltage-level signal. Then, the converting circuit 9 outputs the converted voltage-level signal to the voltage-level switching circuit 7B.

The voltage-level switching circuit 7B switches output to the fans 31 and 32 from an arbitrary voltage-level signal to a voltage-level signal converted by the converting circuit 9, for example, at timing when control has been switched from the BIOS to the OS. For example, the voltage-level switching circuit 7B receives an arbitrary voltage-level signal generated by the voltage generating circuit 6B, and further receives a voltage-level signal converted by the converting circuit 9. Until instructed by the switching instructing unit 8, the voltage-level switching circuit 7B outputs the arbitrary voltage-level signal out of the received voltage-level signals to the fans 31 and 32. Then, at the timing instructed by the switching instructing unit 8, such as timing when the control has been switched from the BIOS to the OS, the voltage-level switching circuit 7B switches output to the fans 31 and 32 from the arbitrary voltage-level signal to the converted voltage-level signal.

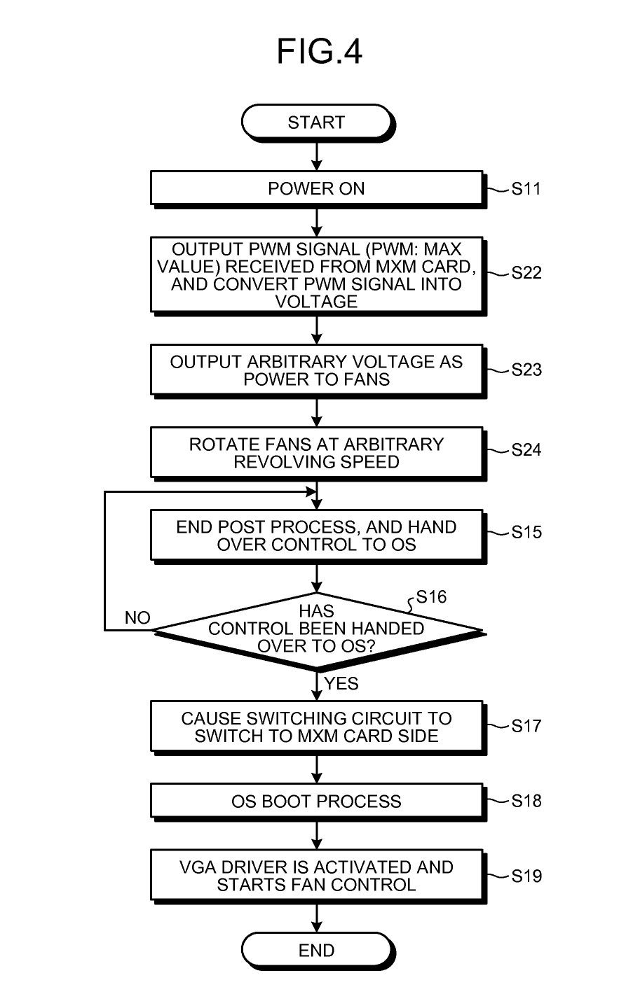

FIG. 4 is a flowchart illustrating a procedure of fan control according to the variation of the first embodiment. In an example illustrated in FIG. 4, a default value of a PWM signal to be output from the MXM card 2 has been set to high (“H”) level. Incidentally, the same step as in the fan control according to the first embodiment is denoted by the same reference numeral, and description of the step is omitted.

First, when the power to a device equipped with the MXM card 2, the fans 31 and 32, and the fan control device 1B is turned on (Step S11), the BIOS initiates a POST process. Then, the MXM card 2 sets a PWM signal to high level, which is the default level, and outputs the PWM signal to the converting circuit 9. The converting circuit 9 converts the PWM signal output from the MXM card 2 into a voltage-level signal, and outputs the voltage-level signal to the voltage-level switching circuit 7B (Step S22).

In parallel with the output of the voltage-level signal from the converting circuit 9, the voltage generating circuit 6B generates an arbitrary voltage-level signal, and outputs the generated arbitrary voltage-level signal as the power to the fans to the voltage-level switching circuit 7B (Step S23). The arbitrary voltage-level signal means a voltage-level signal corresponding to revolving speed which is enough not to make a user of the device feel that the sound of the fans 31 and 32 is noisy and is enough to cool the MXM card 2.

Then, the fans 31 and 32 receive an arbitrary control voltage corresponding to the arbitrary voltage-level signal from the voltage-level switching circuit 7B, and rotate at arbitrary revolving speed corresponding to the received arbitrary control voltage (Step S24). The subsequent steps are the same as in the fan control according to the first embodiment.

Time Chart of Fan Control According to First Embodiment

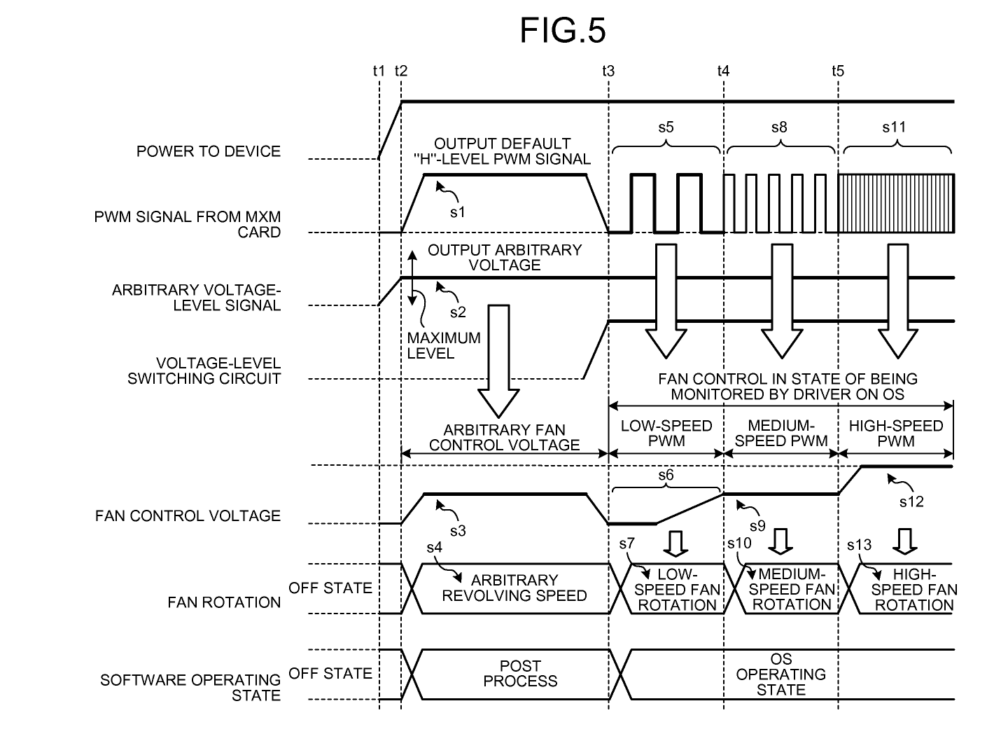

Subsequently, a time chart of the fan control according to the first embodiment is explained with reference to FIG. 5. FIG. 5 is a diagram illustrating the time chart of the fan control according to the first embodiment. In an example illustrated in FIG. 5, a state of a PWM signal to be output from the MXM card 2 makes the transition from the default “H” state to a state of being controlled by the VGA driver 41. Incidentally, in the example illustrated in FIG. 5, the fan control device 1B controls the fans by using a voltage-level signal as a signal controlling the rotation of the fans 31 and 32.

As illustrated in FIG. 5, until a time t1 at which the power to the device is turned on, the device is at rest. Therefore, a PWM signal to be output from the MXM card 2 and an arbitrary voltage-level signal have not yet been generated. When the power to the device is turned on at the time t1, the voltage generating circuit 6B starts generating an arbitrary voltage-level signal.

Then, in a period between a time t2 at which the power to the device is stabilized and a time t3 at which the control is switched from the BIOS to the OS, the BIOS performs the POST process. During this period, the MXM card 2 outputs a default “H”-level PWM signal (s1). In parallel with this, the voltage generating circuit 6B outputs the arbitrary voltage-level signal (s2). Incidentally, the arbitrary voltage-level signal means a voltage-level signal corresponding to revolving speed which is enough not to make a user of the device feel that the sound of the fans 31 and 32 is noisy and is enough to cool the MXM card 2. Here, a level of the arbitrary voltage-level signal is the maximal level of 50%.

Furthermore, during this period, the voltage-level switching circuit 7B sets output to the fans 31 and 32 to the arbitrary voltage-level signal. Therefore, the voltage-level switching circuit 7B outputs an arbitrary fan control voltage (s3) corresponding to the arbitrary voltage-level signal to the fans 31 and 32. Accordingly, the fans 31 and 32 rotate at arbitrary revolving speed (s4) corresponding to the arbitrary fan control voltage.

After that, at the time t3 at which the POST process is ended, the control is switched from the BIOS to the OS. Then, the voltage-level switching circuit 7B switches output to the fans 31 and 32 from the arbitrary voltage-level signal to a voltage-level signal corresponding to the PWM signal output from the MXM card 2. Then, when the OS goes into an operating state, the VGA driver 41 is activated, and the VGA driver 41 goes into a state capable of monitoring the temperature of the MXM card 2 and causes the MXM card 2 to output a PWM signal according to the temperature of the MXM card 2.

Then, until a time t4 since the OS has gone into the operating state, the MXM card 2 outputs a PWM signal (s5) controlling the fan revolving speed to low speed. Therefore, the voltage-level switching circuit 7B outputs a fan control voltage (s6) corresponding to the PWM signal to the fans 31 and 32. Accordingly, the fans 31 and 32 rotate at low revolving speed (s7) corresponding to the fan control voltage.

Then, in a period between the time t4 and a time t5, the MXM card 2 outputs a PWM signal (s8) controlling the fan revolving speed to medium speed. Therefore, the voltage-level switching circuit 7B outputs a fan control voltage (s9) corresponding to the PWM signal to the fans 31 and 32. Accordingly, the fans 31 and 32 rotate at medium revolving speed (s10) corresponding to the fan control voltage.

Then, after the time t5, the MXM card 2 outputs a PWM signal (s11) controlling the fan revolving speed to high speed. Therefore, the voltage-level switching circuit 7B outputs a fan control voltage (s12) corresponding to the PWM signal to the fans 31 and 32. Accordingly, the fans 31 and 32 rotate at high revolving speed (s13) corresponding to the fan control voltage.

### Effects of First Embodiment

According to the above-described first embodiment, the fan control device 1A includes the PWM generating circuit 6A that generates an arbitrary PWM signal controlling the rotation of the fans 31 and 32 for cooling the MXM card 2 which is a heat-generating component. The fan control device 1A further includes the PWM switching circuit 7A in between the MXM card 2 and the fans 31 and 32; the PWM switching circuit 7A switches output to the fans 31 and 32 from the arbitrary PWM signal generated by the PWM generating circuit 6A to a PWM signal output from the MXM card 2. The fan control device 1A still further includes the switching instructing unit 8 that issues a switching instruction to the PWM switching circuit 7A at predetermined timing. According to this configuration, the fan control device 1A switches output to the fans from the arbitrary PWM signal to the PWM signal output from the MXM card 2 at the predetermined timing, and therefore the fan control device 1A can appropriately control the rotation of the fans in a period in which a PWM signal to be output from the MXM card 2 is not controlled.

Furthermore, according to the above-described first embodiment, when control has been switched from the BIOS to the OS, the switching instructing unit 8 issues a switching instruction to the PWM switching circuit 7A. According to this configuration, when the control has been switched from the BIOS to the OS, the PWM switching circuit 7A switches output to the fans from the arbitrary PWM signal generated by the PWM generating circuit 6A to the PWM signal output from the MXM card 2. Therefore, after the control has been switched from the BIOS to the OS, the PWM switching circuit 7A can output an appropriate PWM signal controlled by the driver that controls the rotation of the fans for cooling the MXM card 2 to the fans. On the other hand, until the control has been switched from the BIOS to the OS, the PWM switching circuit 7A outputs the arbitrary PWM signal. Therefore, the PWM switching circuit 7A can output an arbitrary PWM signal controlling the fans, for example, not to rotate at the maximum revolving speed in a period in which the driver of the MXM card 2 is not activated, and thus it is possible to solve the problem that a user feels the sound of the fans is noisy. Furthermore, the PWM switching circuit 7A can output an arbitrary PWM signal controlling the fans, for example, not to stop rotating in the period in which the driver of the MXM card 2 is not activated, and thus it is possible to solve the problem that the temperature of the MXM card 2 is extremely raised.

Moreover, according to the above-described first embodiment, the fan control device 1B includes the converting circuit 9 in between the MXM card 2 and the voltage-level switching circuit 7B; the converting circuit 9 converts a PWM signal output from the MXM card 2 into a voltage-level signal if a signal controlling the rotation of the fans is a voltage-level signal. Then, the voltage-level switching circuit 7B switches output to the fans 31 and 32 from an arbitrary voltage-level signal generated by the voltage generating circuit 6B to the voltage-level signal converted by the converting circuit 9. According to this configuration, at predetermined timing, the fan control device 1B switches output to the fans from an arbitrary voltage signal to a voltage signal into which the PWM signal output from the MXM card 2 is converted. Therefore, the fan control device 1B can appropriately control the rotation of the fans in a period in which a PWM signal output from the MXM card 2 is not controlled.

### [b] Second Embodiment

In the fan control device 1A according to the first embodiment, the switching instructing unit 8 issues a switching instruction to the PWM switching circuit 7A at timing when the control has been switched from the BIOS to the OS. However, the timing is not limited to this, and the switching instructing unit 8 of the fan control device 1A can be configured to issue a switching instruction to the PWM switching circuit 7A upon receipt of an instruction from a user.

In a second embodiment, there is explained the case where the switching instructing unit 8 issues a switching instruction to the PWM switching circuit 7A upon receipt of an instruction from a user.

Configuration of Fan Control Device According to Second Embodiment

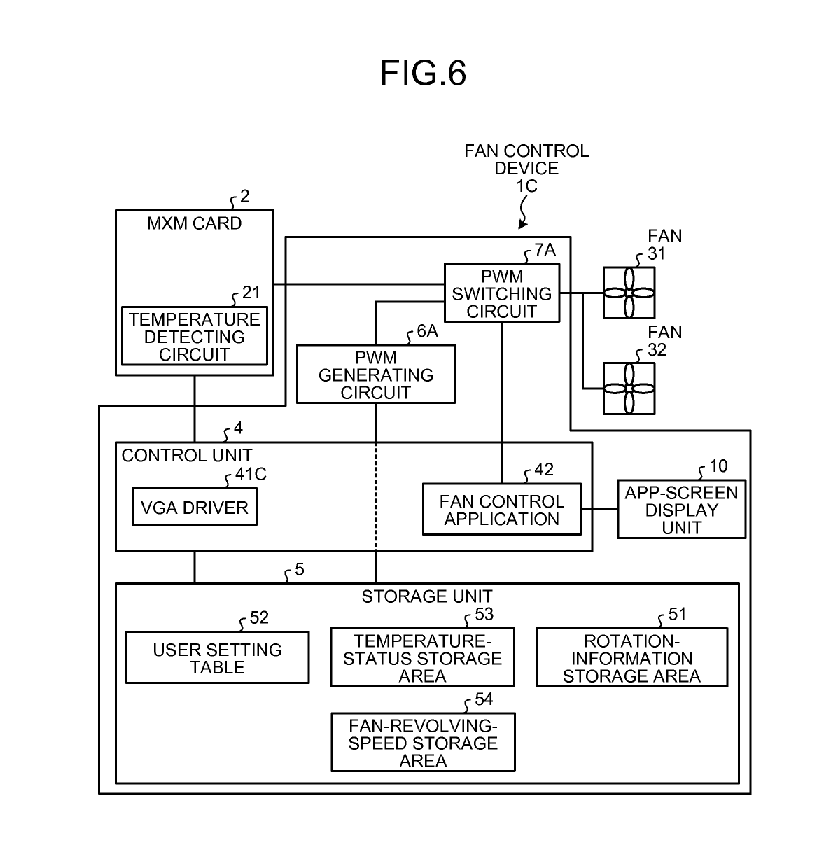

FIG. 6 is a block diagram illustrating a configuration of a fan control device according to the second embodiment. Incidentally, the same component as in the fan control device 1A illustrated in FIG. 1 is denoted by the same reference numeral, and description of the component and its operation is omitted. The second embodiment differs from the first embodiment in that the control unit 4 further includes a fan control application 42 and includes a VGA driver 41C instead of the VGA driver 41. Furthermore, the second embodiment differs from the first embodiment in that a fan control device 1C according to the second embodiment further includes an app-screen display unit 10. Moreover, the second embodiment differs from the first embodiment in that the storage unit 5 further includes a user setting table 52, a temperature-status storage area 53, and a fan-revolving-speed storage area 54.

The app-screen display unit 10 is a display device that displays thereon various kinds of information, such as a screen output from the fan control application 42. For example of the app-screen display unit 10, a monitor, a display, and a touch panel, etc. can be applied.

The fan control application 42 issues a switching instruction to the PWM switching circuit 7A upon receipt of an instruction from a user. For example, when the fan control application 42 has received a PWM-signal switching instruction through the screen displayed on the app-screen display unit 10, the fan control application 42 instructs the PWM switching circuit 7A to switch from an arbitrary PWM signal to a PWM signal output from the MXM card 2. For example, the timing to receive an instruction from a user is when the user feels that the sound produced by the rotation of the fans is noisy or when the user feels that the temperature of a device equipped with the MXM card 2 is raised to high temperature, etc. Furthermore, the arbitrary PWM signal means a PWM signal corresponding to revolving speed which is enough not to make the user feel that the sound of the fans 31 and 32 is noisy and is enough to cool the MXM card 2.

Furthermore, the fan control application 42 changes the user setting table 52 used in the fan control by the VGA driver 41C on the basis of an instruction through the screen displayed on the app-screen display unit 10. Here, the user setting table 52 stores therein alterable fan rotation information in a manner associated with a possible temperature of the MXM card 2. For example, the user setting table 52 stores therein a possible temperature of the MXM card 2 and the percentage of fan revolving speed in an associated manner. The percentage of fan revolving speed here means the percentage of fan revolving speed to the maximum fan revolving speed. This user setting table 52 is set in advance of the operation of the device, and may be changed by a user during the operation of the device.

The VGA driver 41C controls the rotation of the fans 31 and 32 according to temperature of the MXM card 2 after the OS has booted and the PWM switching circuit 7A has switched the output to the fans 31 and 32. For example, on the basis of the temperature and percentage of fan revolving speed stored in the user setting table 52, the VGA driver 41C causes the MXM card 2 to output a PWM signal controlling the rotation of the fans corresponding to the temperature of the MXM card 2. Namely, the VGA driver 41C is not activated until the OS boots up, and therefore does not control a PWM signal according to temperature of the MXM card 2 and leaves the control of the rotation of the fans to an arbitrary PWM signal. Then, even after the OS has booted, until the PWM switching circuit 7A has switched the output to the fans 31 and 32, the VGA driver 41C leaves the control of the rotation of the fans to an arbitrary PWM signal. Then, after the PWM switching circuit 7A has switched the output to the fans 31 and 32, the VGA driver 41C controls the rotation of the fans using the user setting table 52.

The temperature-status storage area 53 stores therein the current temperature of the MXM card 2. The fan-revolving-speed storage area 54 stores therein the current revolving speed of the fans 31 and 32.

Procedure of Fan Control According to Second Embodiment

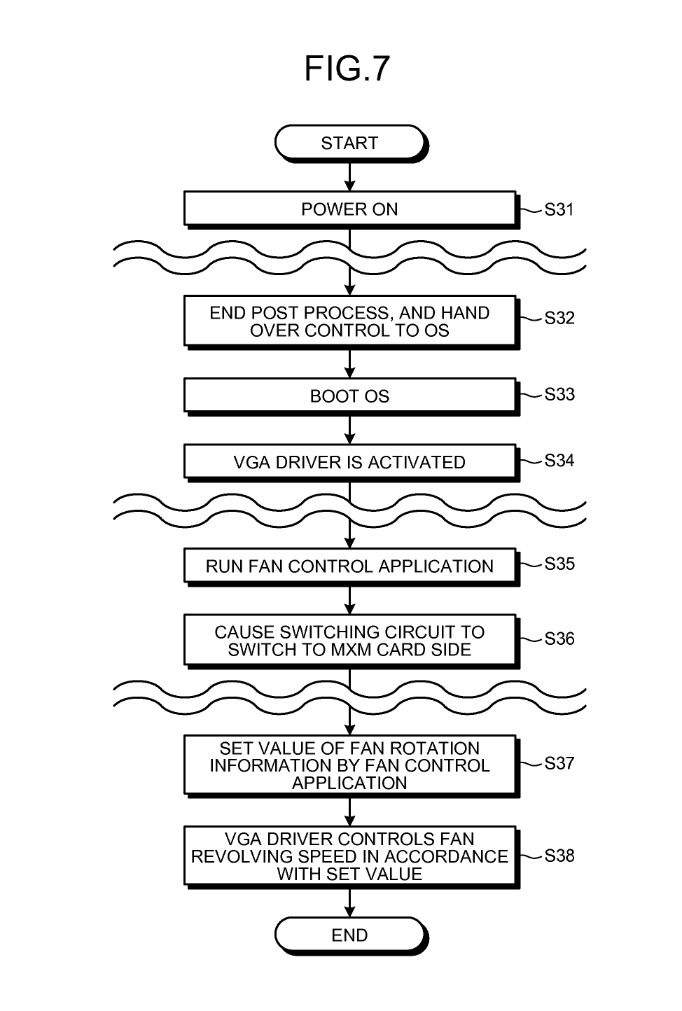

Subsequently, a procedure of the fan control according to the second embodiment is explained with reference to FIG. 7. FIG. 7 is a flowchart illustrating the procedure of the fan control according to the second embodiment. In an example illustrated in FIG. 7, a default value of a PWM signal output from the MXM card 2 has been set to high (“H”) level.

First, when the power to a device equipped with the MXM card 2, the fans 31 and 32, and the fan control device 1C is turned on (Step S31), the BIOS initiates a POST process. At this time, the MXM card 2 sets a PWM signal to high level, which is the default level, and outputs the PWM signal to the PWM switching circuit 7A. In parallel with this, the PWM generating circuit 6A generates an arbitrary PWM signal, and outputs the arbitrary PWM signal to the PWM switching circuit 7A. Then, the fans 31 and 32 receive the arbitrary PWM signal from the PWM switching circuit 7A, and rotate at revolving speed corresponding to the received arbitrary PWM signal.

After that, the BIOS ends the POST process, and hands over the control to the OS (Step S32). The OS boots up (Step S33), and, after the boot, the VGA driver 41C is activated (Step S34).

A user runs the fan control application 42 in a state where the OS is running (Step S35). After the boot-up, the fan control application 42 issues a switching instruction to the PWM switching circuit 7A upon receipt of an instruction from the user, and causes the PWM switching circuit 7A to switch from the arbitrary PWM signal to the PWM signal output from the MXM card 2 (Step S36). As a result, after the switching by the PWM switching circuit 7A, the VGA driver 41C controls the rotation of the fans 31 and 32 using the user setting table 52.

After that, if the fan control application 42 has received an instruction to change the fan rotation information through the screen displayed on the app-screen display unit 10, the fan control application 42 sets a value of the fan rotation information instructed to be changed thereto in the user setting table 52 (Step S37). After that, the VGA driver 41C controls the fan revolving speed in accordance with the value set in the user setting table 52 (Step S38).

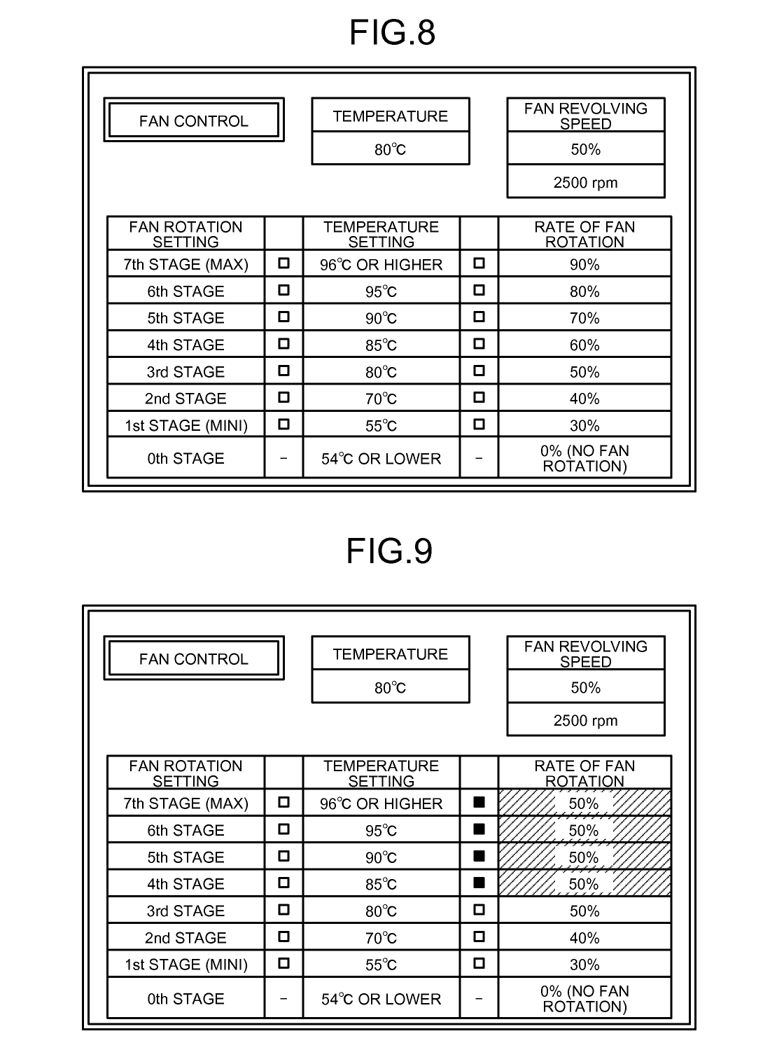

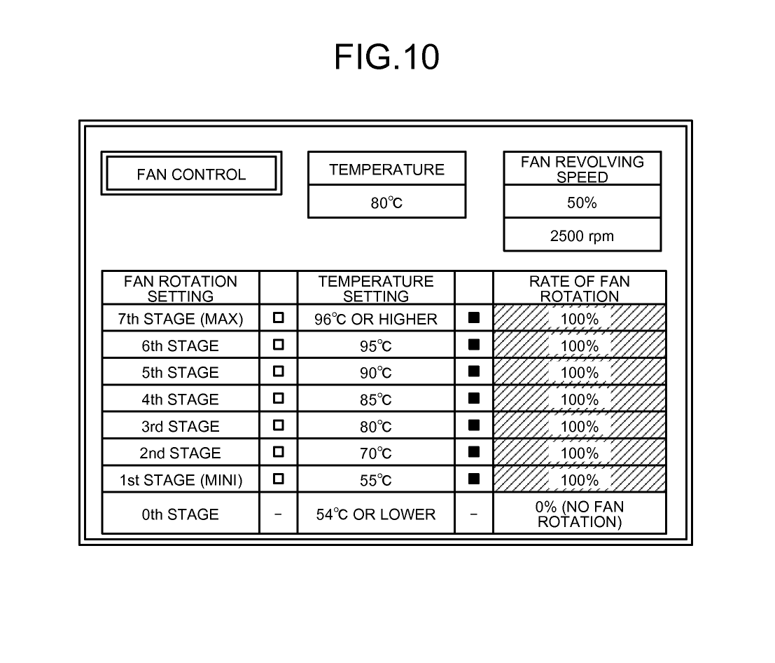

Subsequently, a screen example of the fan control application 42 according to the second embodiment is explained with reference to FIGS. 8 to 10. FIG. 8 illustrates an example of a default screen of the fan control application. FIG. 9 illustrates a setting example of the screen of the fan control application when a user wants to decrease the volume of sound produced by the rotation of the fans. FIG. 10 illustrates a setting example of the screen of the fan control application when the user wants to lower the temperature of the device body.

As illustrated in FIG. 8, temperature, fan revolving speed, fan rotation setting, and temperature setting, and a rate of fan rotation are displayed on the screen of the fan control application 42. The temperature is the current temperature of the MXM card 2. For example, the VGA driver 41C stores the detected temperature of the MXM card 2 in the temperature-status storage area 53, and the fan control application 42 displays thereon the temperature stored in the temperature-status storage area 53.

The fan revolving speed is the current fan revolving speed. For example, the percentage of fan revolving speed and the fan revolving speed which are used in the control of the rotation of the fans according to the temperature of the MXM card 2 by the VGA driver 41C are displayed. In the fan rotation setting, eight stages of fan revolving speeds according to temperature including non-rotation setting can be set. In the temperature setting, temperatures for the seven stages, excluding the 0th stage, can be set. In the rate of fan rotation, a rate of fan rotation corresponding to fan revolving speed when the temperature reaches a target temperature can be set.

For example, in the 0th stage, when a target temperature is 54° C. or lower, a rate of fan rotation is 0% which means non-rotation. In the first stage, when a target temperature is 55° C., a rate of fan rotation is 30%. Then, in the seventh stage, when a target temperature is 96° C. or higher, a rate of fan rotation is 90%.

As illustrated in FIG. 9, the screen of the fan control application 42 displays that rates of fan rotation in the fourth to seventh stages in which the fan revolving speed is increased are set to 50%. Consequently, when a user feels that the sound produced by the rotation of the fans is noisy, fan rotation noise and wind noise can be reduced by setting the rates of fan rotation lower.

As illustrated in FIG. 10, the screen of the fan control application 42 displays that rates of fan rotation in all stages except for the 0th stage are set to 100%. Consequently, when a user feels that the temperature of the device body is raised, the device body can be efficiently cooled by setting the rates of fan rotation lower.

### Effects of Second Embodiment

According to the above-described second embodiment, the fan control application 42 of the fan control device 1C issues a switching instruction to the PWM switching circuit 7A upon receipt of an instruction from a user. According to this configuration, the fan control application 42 can achieve the switching by the PWM switching circuit 7A meeting a user's request.

Furthermore, according to the above-described second embodiment, the fan control device 1C includes the user setting table 52 that stores therein alterable rotation information of the fans 31 and 32 in a manner associated with a possible temperature of the MXM card 2 corresponding to a heat-generating component. And, the fan control device 1C further includes the VGA driver 41C that causes the MXM card 2 to output a signal controlling the rotation of the fans corresponding to the temperature of the MXM card 2 on the basis of the temperature and fan rotation information stored in the user setting table 52. According to this configuration, the fan rotation information associated with temperature in the user setting table 52 can be altered, and therefore the fan control device 1C can control the rotation of the fans according to a user's sense which is different from one individual to another.

Example of Hardware Configuration using Fan Control

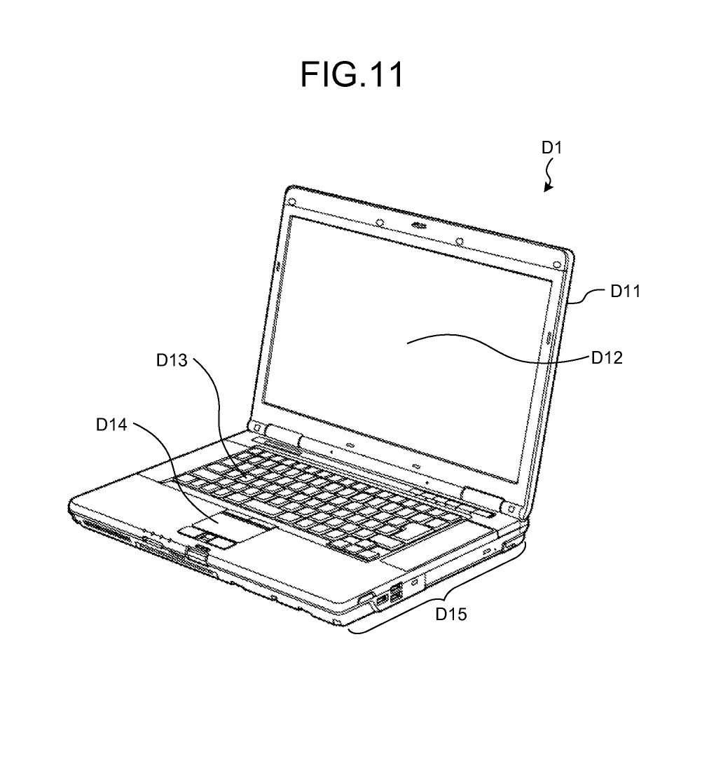

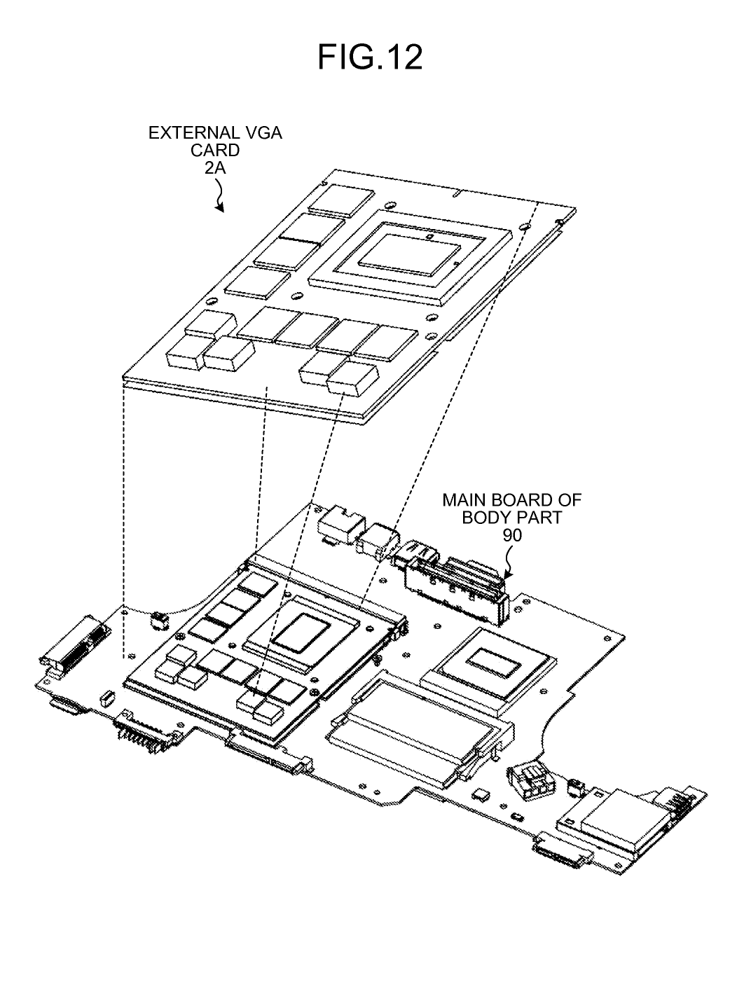

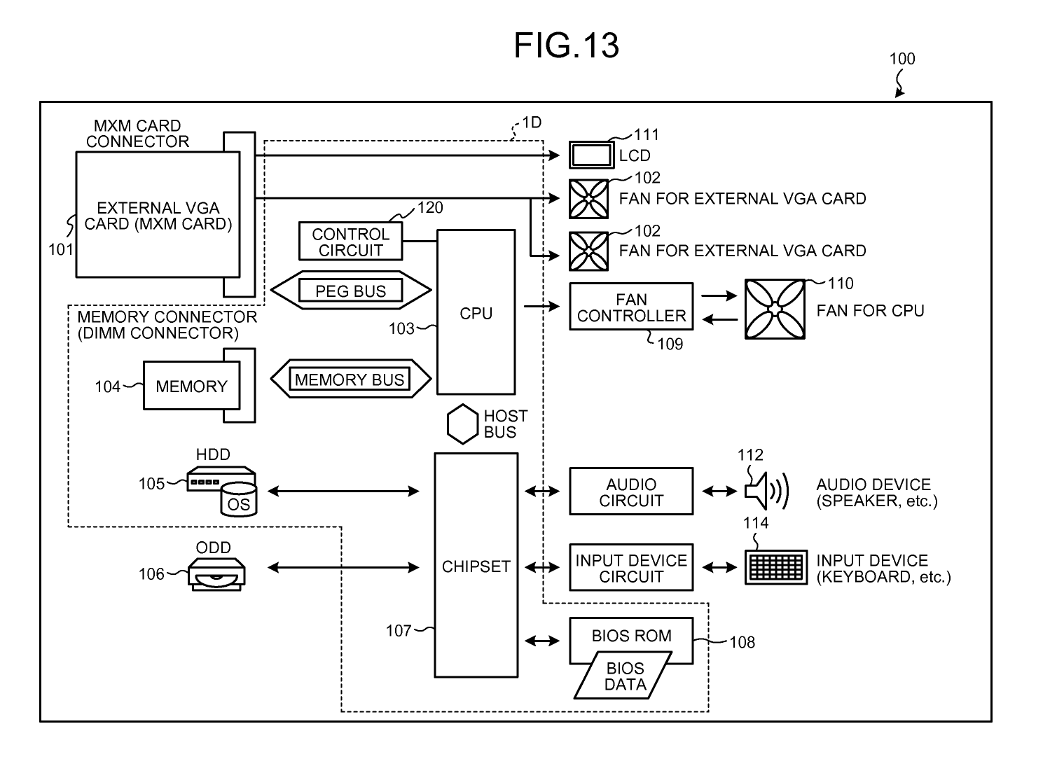

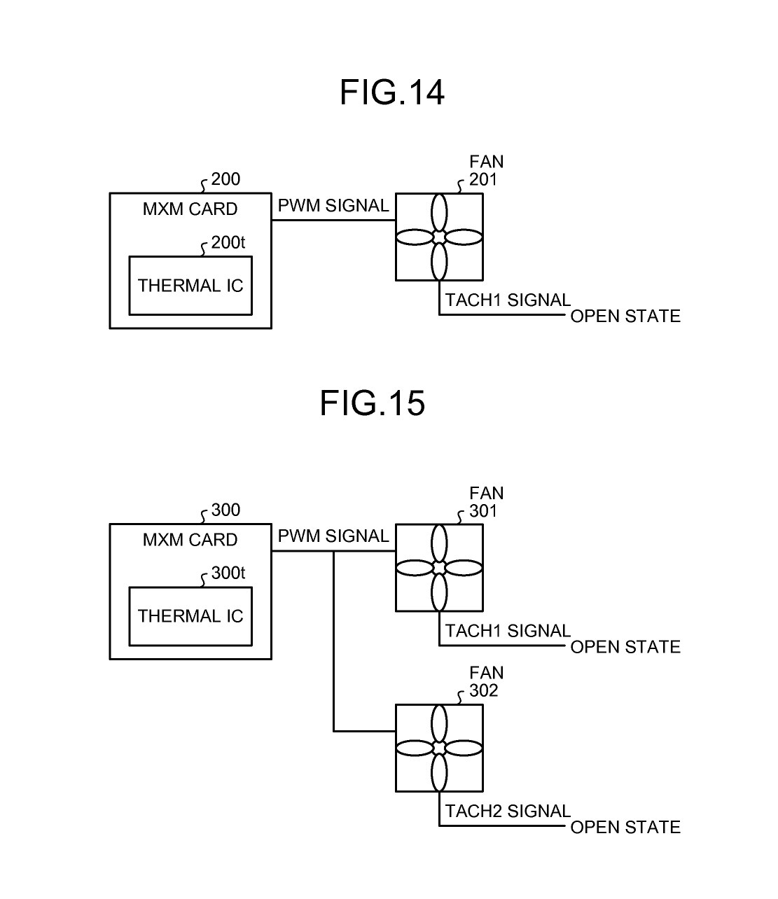

An example of a hardware configuration using the fan control according to the embodiment is explained with reference to FIGS. 11 to 13. FIG. 11 illustrates an example of the concept of a mobile workstation using the fan control according to the embodiment. FIG. 12 illustrates an example of the mounting location of a VGA card in a body part. FIG. 13 illustrates an example of a hardware configuration of the mobile workstation using the fan control according to the embodiment.

As illustrated in FIG. 11, there is a notebook workstation D1 as the mobile workstation using the fan control. The notebook workstation D1 includes a display unit D11, a display part D12, a keyboard D13, a touchpad D14, and a body part D15. As illustrated in FIG. 12, an external VGA card 2A as an example of the MXM card 2 is mounted on a main board 90 of the body part D15. This external VGA card 2A is independent of the main board, and can be changed.

As illustrated in FIG. 13, a mobile workstation 100 includes an external VGA card 101, two fans 102 for the external VGA card, a control circuit 120, a CPU 103, a memory 104, and a hard disk drive (HDD) 105. Furthermore, the mobile workstation 100 further includes an optical disk drive (ODD) 106, a chipset 107, a BIOS read-only memory (ROM) 108, a fan controller 109, and a fan 110 for the CPU. Moreover, the mobile workstation 100 still further includes a liquid crystal display (LCD) 111, an audio device 112, and an input device 114. The external VGA card 101, the control circuit 120, the memory 104, and the chipset 107 are each connected to the CPU 103 via a bus.

The control circuit 120 is a circuit having the same functions as the PWM generating circuit 6A, the PWM switching circuit 7A, and the switching instructing unit 8 illustrated in FIG. 1. An area denoted by a reference numeral 1D represents a device having the same function as the fan control device 1A illustrated in FIG. 1.

A VGA driver having the same function as the control unit 4 illustrated in FIG. 1 is stored in the HDD 105. Furthermore, an OS and rotation information corresponding to the rotation-information storage area 51 illustrated in FIG. 1 are stored in the HDD 105. After the OS boots up, the CPU 103 reads out the VGA driver from the HDD 105, and loads the VGA driver into the memory 104, thereby the VGA driver runs on the OS.

The external VGA card 101 outputs a PWM signal controlling the fans to the control circuit 120. The control circuit 120 generates an arbitrary PWM signal, and outputs the generated arbitrary PWM signal to the fans 102 for the external VGA card. Then, the control circuit 120 switches from the arbitrary PWM signal to a PWM signal output from the external VGA card 101 at predetermined timing.

Others

Incidentally, it is described that the fan control devices 1A to 1C do not include the MXM card 2 and the fans 31 and 32. However, the fan control devices 1A to 1C are not limited to this, and can be configured to include the MXM card 2 and the fans 31 and 32.

Furthermore, it is described that in the fan control devices 1A to 1C, the PWM generating circuit 6A or the voltage generating circuit 6B reads out arbitrary revolving speed stored in the rotation-information storage area 51, and generates a PWM signal corresponding to the read arbitrary revolving speed. However, the PWM generating circuit 6A and the voltage generating circuit 6B are not limited to this, and can be configured to generate a PWM signal corresponding to arbitrary revolving speed set in advance.

Moreover, the fan control devices 1A to 1C can be realized by equipping an information processing apparatus, such as a known personal computer or workstation, with the functions of the PWM generating circuit 6A, the PWM switching circuit 7A, and the switching instructing unit 8, etc.

Furthermore, the components of the fan control devices 1A to 1C illustrated in the drawings do not always have to be physically configured as illustrated in the drawings. Namely, the specific forms of division and integration of the components of each device are not limited to those illustrated in the drawings, and all or some of the components can be configured to be functionally or physically divided or integrated in arbitrary units depending on respective loads and use conditions, etc. For example, the PWM generating circuit 6A and the PWM switching circuit 7A can be integrated into one unit. Furthermore, the storage unit 5 can be integrated into the PWM generating circuit 6A, or the storage unit 5 can be an external device connected to the fan control device 1A via a bus or a network.

Moreover, all or any part of processing functions implemented in the fan control devices 1A to 1C can be realized as a CPU (or a microcomputer, such as a micro-processing unit (MPU) and a micro controller unit (MCU)) or hardware by wired logic. Furthermore, all or any part of the processing functions implemented in the fan control devices 1A to 1C can be realized by a program that is analyzed and executed by a CPU (or a microcomputer, such as an MPU and an MCU).

According to one aspect of a fan control device discussed in the present application, the fan control device can appropriately control a fan for cooling a heat-generating component.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A fan control device comprising:
a signal generating circuit that generates an arbitrary signal controlling rotation of a fan for cooling a heat-generating component;
a switching circuit that is located between the heat-generating component and the fan, and switches output to the fan from the arbitrary signal generated by the signal generating circuit to a signal output by the heat-generating component; and
a switching instructing unit that issues a switching instruction to the switching circuit at predetermined timing.

2. The fan control device according to claim 1, wherein
when a control has been switched from a first program to a second program, the switching instructing unit issues the switching instruction to the switching circuit.

3. The fan control device according to claim 1, wherein
when having received an instruction from a user, the switching instructing unit issues the switching instruction to the switching circuit.

4. The fan control device according to claim 1, further comprising:
a storage unit that stores therein alterable rotation information of the fan in a manner associated with a possible temperature of the heat-generating component; and
a control unit that causes the heat-generating component to output a signal controlling the rotation of the fan corresponding to temperature of the heat-generating component on the basis of the temperature and the rotation information of the fan which have been stored in the storage unit.

5. The fan control device according to claim 1, further comprising a converting circuit that is located between the heat-generating component and the switching circuit, and converts, when a signal controlling the rotation of the fan is a voltage signal, the signal output by the heat-generating component into a voltage signal, wherein
the switching circuit switches output to the fan from the arbitrary voltage signal generated by the signal generating circuit to the voltage signal converted by the converting circuit.

6. A fan control method for controlling rotation of a fan for cooling a heat-generating component, the fan control method comprising:
inputting a signal output by the heat-generating component and an arbitrary signal controlling rotation of the fan to a switching circuit that switches output to the fan; and
switching output to the fan from the arbitrary signal to the signal output by the heat-generating component when the switching circuit has received a switching instruction at predetermined timing.
